(19) United States
(12) Patent Application Publication
(10) Pub. No.: US 2025/0140585 A1
(43) Pub. Date: May 1, 2025

(54) SUBSTRATE PROCESSING APPARATUS AND SUBSTRATE PROCESSING METHOD

(71) Applicant: Tokyo Electron Limited, Minato-ku, Tokyo (JP)

(72) Inventor: Shogo FUKUI, Koshi City, Kumamoto (JP)

(21) Appl. No.: 18/835,377

(22) PCT Filed: Jan. 26, 2023
(86) PCT No.: PCT/JP2023/002392

§ 371 Date: Aug. 2, 2024

(30) Foreign Application Priority Data
Feb. 8, 2022 (JP) 2022-018193

(51) Int. Cl. H01L 21/67; H01L 21/02

(52) U.S. Cl. CPC H01L 21/67248; H01L 21/02101; H01L 21/67034

(57) ABSTRACT

A substrate processing apparatus includes a processing container, a fluid supplier, a heating mechanism, a temperature meter, and a controller, and dries a substrate having a liquid film using a supercritical fluid. The controller acquires information on a temperature of an interior of the processing container measured by the temperature meter from when the substrate is loaded into the processing container until the substrate is unloaded therefrom, stores temperature-time data, extracts a temperature from the stored temperature-time data during a temperature adjustment target period, determines whether or not correction of a set temperature of the heating mechanism is necessary based on comparison between the temperature during the temperature adjustment target period and a reference temperature held in advance, and, when the correction of the set temperature is determined to be necessary, controls an output of the heating mechanism according to the corrected set temperature.

### TECHNICAL FIELD

The present disclosure relates to a substrate processing apparatus and a substrate processing method.

### BACKGROUND

Patent Document 1 discloses a substrate processing apparatus that performs substrate processing to dry a substrate by supplying a supercritical fluid to an interior of a processing container. The supercritical fluid dries a liquid film formed on the substrate by transitioning directly from a supercritical state where there is no interface between gas and liquid to a vapor phase (that is, by ensuring that surface tension does not act on uneven patterns of the substrate). This type of substrate processing apparatus appropriately controls a temperature for each of multiple repetitions of substrate processing, thereby promoting the uniformity of process performance for each substrate processing.

### PRIOR ART DOCUMENT

### Patent Document

Patent Document 1: Japanese Laid-Open Patent Publication No. 2013-026348

### SUMMARY

The present disclosure provides a technique capable of further promoting uniformity of temperature for each substrate processing.

According to an aspect of the present disclosure, a substrate processing apparatus for drying a substrate having a liquid film using a supercritical fluid, includes: a processing container in which the substrate is accommodated; a fluid supplier configured to supply the supercritical fluid to an interior of the processing container; a heating mechanism configured to heat the interior of the processing container; a temperature meter configured to measure a temperature of the interior of the processing container; and a controller configured to control the fluid supplier and the heating mechanism. The controller is configured to: acquire temperature information on the temperature of the interior of the processing container measured by the temperature meter during a duration from when the substrate is loaded to the interior of the processing container until the substrate is unloaded from the processing container, and store temperature-time data in which the temperature information is associated with time; extract a temperature during a temperature adjustment target period from the stored temperature-time data, and determine whether or not correction of a set temperature of the heating mechanism is necessary based on comparison between the temperature during the temperature adjustment target period and a reference temperature held in advance; and when the correction of the set temperature is determined to be necessary, correct the set temperature and control an output of the heating mechanism according to the corrected set temperature.

According to one aspect, it is possible to further promote uniformity of temperature for each substrate processing.

### BRIEF DESCRIPTION OF DRAWINGS

FIG. 1 is a schematic perspective view illustrating a substrate processing apparatus according to one embodiment.

FIG. 2 is a schematic side cross-sectional view illustrating the substrate processing apparatus of FIG. 1.

FIG. 3 is a flowchart illustrating a substrate processing method performed by the substrate processing apparatus.

FIG. 4 is a graph illustrating a variation in an internal temperature of a processing container in each operation of supercritical drying.

FIG. 5 is a schematic diagram illustrating an in-plane temperature distribution of a substrate when the substrate is arranged in a processing chamber without a temperature correction after multiple repetitions of supercritical drying.

FIG. 6A is a schematic plan view illustrating a configuration of a heating mechanism provided on a side of a ceiling wall of the processing container, and FIG. 6B is a schematic perspective view illustrating a sensor heater unit on an enlarged scale.

FIG. 7 is a block diagram illustrating functional components of a controller performing constant temperature control and temperature distribution uniformization control.

FIG. 8 is a flowchart illustrating a substrate processing method including the constant temperature control and the temperature distribution uniformization control.

FIG. 9 is a schematic side cross-sectional view illustrating a substrate processing apparatus according to Modification.

### DETAILED DESCRIPTION

Hereinafter, embodiments for carrying out the present disclosure will be described with reference to the drawings. In each drawing, the same reference numerals will be given to the same components, and redundant descriptions thereof will be omitted.

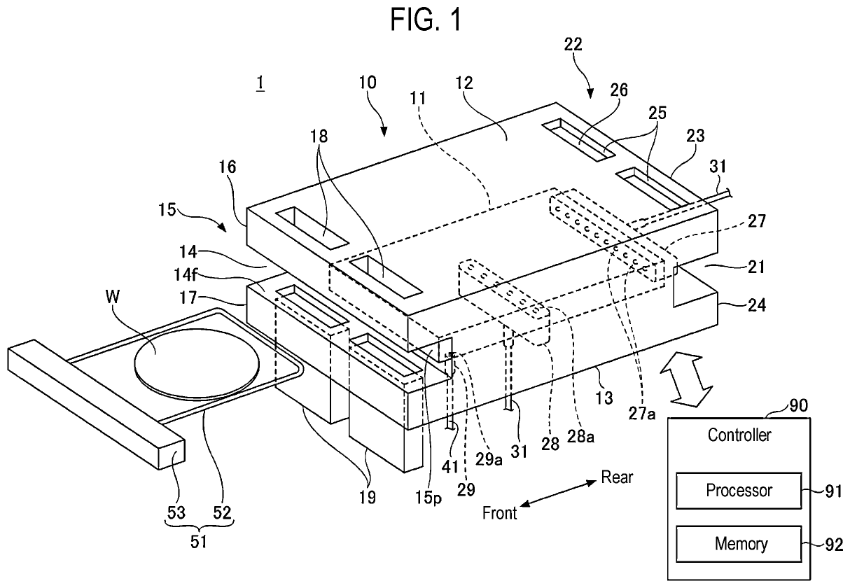

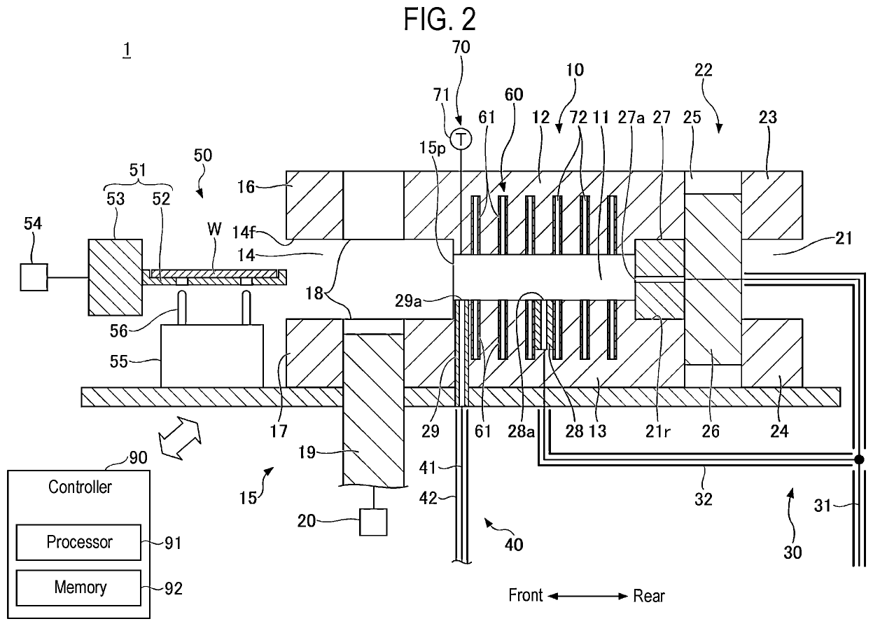

First, a configuration of a substrate processing apparatus 1 according to one embodiment will be described with reference to FIGS. 1 and 2. The substrate processing apparatus 1 performs substrate processing to dry a substrate W by replacing a liquid film of drying liquid formed on the substrate W with a supercritical fluid (hereinafter, drying using the supercritical fluid is also referred to as “supercritical drying”). The supercritical fluid is a fluid in a state where distinction between liquid and gas is not discernible by being at a temperature and pressure at or above a critical temperature and pressure. If the liquid film such as drying liquid is replaced with the supercritical fluid, it is possible to eliminate the interface between liquid and gas in uneven patterns of the substrate W. As a result, the surface tension of liquid does not occur, which may prevent the collapse of uneven patterns.

The drying liquid forming the liquid film is, for example, an organic solvent such as isopropyl alcohol (IPA). Examples of the supercritical fluid may include carbon dioxide, ethanol, methanol, propanol, butanol, methane, ethane, propane, water, ammonia, ethylene, and fluoromethane. Hereinafter, an example of using the carbon dioxide as the supercritical fluid will be described as a representative example.

The substrate processing apparatus 1 includes a processing container 10, a fluid supplier 30 for supplying a fluid to the processing container 10, a fluid discharger 40 for discharging the fluid from the processing container 10, a substrate transferor 50 for transferring the substrate W to the processing container 10, and a heating mechanism 60 for heating the processing container 10. Further, the substrate processing apparatus 1 includes a controller 90 for controlling the operation of each component.

The processing container 10 is formed as a substantially rectangular box, and accommodates the substrate W with the liquid film of drying liquid in an internal processing chamber 11 thereof to process the substrate W. The processing chamber 11 has a rectangular space, which is wide in a horizontal direction but narrow in a vertical direction, to accommodate the substrate W which is a thin plate and has a circular shape. A ceiling wall 12 and a bottom wall 13 of the processing container 10, which enclose the processing chamber 11, are thicker than a vertical height of the processing chamber 11.

The processing container 10 has a recessed space 14 in the middle of the vertical direction on the front side thereof, which is depressed toward the rear side (the processing chamber 11 side). The front side of the processing container 10 constitutes a loading/unloading mechanism 15 for fixing the substrate transferor 50 when the substrate W has been loaded into the processing chamber 11. The loading/unloading mechanism 15 has a front opening 14f for introducing the substrate transferor 50 into the recessed space 14, and also has a loading/unloading port 15p communicating with the processing chamber 11 on the rear of the recessed space 14.

Further, one or more (two in the present embodiment) through-holes 18 are formed in each of an upper wall 16 and a lower wall 17 of the processing container 10 with the recessed space 14 interposed therebetween. Each through-hole 18 in the upper wall 16 and each through-hole 18 in the lower wall 17 are formed in a rectangular shape in a plan view and face each other. The loading/unloading mechanism 15 accommodates front blocking members 19 respectively in a pair of through-holes 18 in the lower wall 17. Further, the loading/unloading mechanism 15 includes a lifting drive 20 below the processing container 10 to simultaneously raise or lower both the front blocking members 19.

Each front blocking member 19 is formed as a rectangular block and is raised or lowered along the vertical direction via each through-hole 18 with the operation of the lifting drive 20. Once the substrate transferor 50 has loaded the substrate W into the processing chamber 11, each front blocking member 19 passes through the recessed space 14 from each through-hole 18 in the lower wall 17 and is also inserted into each through-hole 18 in the upper wall 16. Arranging each front blocking member 19 across each through-hole 18 in the upper wall 16 and each through-hole 18 in the lower wall 17 ensures that the loading/unloading mechanism 15 may firmly fix the substrate transferor 50 to the processing container 10.

Further, the processing container 10 has a recessed space 21 in the middle of the vertical direction on the rear side thereof, which is depressed towards the front side (the processing chamber 11 side). The rear side of the processing container 10 constitutes a fluid discharge fixing mechanism 22 for fixing a first supply header 27 which discharges the supercritical fluid. The fluid discharge fixing mechanism 22 has a placement portion 21r communicating with the processing chamber 11 on the front side of the recessed space 21. The first supply header 27 is accommodated in the placement portion 21r.

Similar to the loading/unloading mechanism 15, one or more (two in the present embodiment) through-holes 25 are formed in each of an upper wall 23 and a lower wall 24 of the processing container 10 with the recessed space 21 interposed therebetween. Each through-hole 25 in the upper wall 23 and each through-hole 25 in the lower wall 24 face each other. However, a rear blocking member 26 is inserted into each through-hole 25 in advance to fix the first supply header 27. The rear blocking member 26 is fixed immovably during operation such as the supercritical drying, but may be separated during maintenance or the like so that the first supply header 27 may be removed from the processing container 10.

The first supply header 27 accommodated in the placement portion 21r of the processing container 10 airtightly blocks the rear side of the processing chamber 11. The first supply header 27 is connected to the fluid supplier 30 and has a plurality of discharge ports 27a to discharge the supercritical fluid to an exposed surface of the processing chamber 11. The plurality of discharge ports 27a are arranged in a line at equal intervals along a transverse direction (horizontal direction) of the processing chamber 11.

Further, the processing container 10 includes a second supply header 28 at the longitudinal center position of the bottom wall 13. The second supply header 28 is also connected to the fluid supplier 30 and has a plurality of discharge ports 28a to discharge the supercritical fluid to the exposed surface of the processing chamber 11. The plurality of discharge ports 28a are arranged in a line at equal intervals along the transverse direction (horizontal direction) of the processing chamber 11.

The fluid supplier 30 has a supply path 31 connected to both the first supply header 27 and the second supply header 28, and supplies the supercritical fluid via the supply path 31. The supply path 31 is connected at an upstream end thereof to a fluid source (not illustrated) and is branched at intermediate positions along the first supply header 27 and the second supply header 28. Further, the fluid supplier 30 includes a supply-side heater 32, as well as a pump, flow adjusters, on/off valves, and the like, which are not illustrated, at intermediate positions of the supply path 31. The fluid supplier 30 is connected to the controller 90 of the substrate processing apparatus 1. Each component of the fluid supplier 30 is controlled by the controller 90.

The fluid source uses a high-pressure tank, and the like, and releases the supercritical fluid (CO₂) stored in the tank to the supply path 31. The supply-side heater 32 heats the supercritical fluid supplied from the fluid source to maintain the temperature of the supercritical fluid at or above the critical temperature. For example, the supply-side heater 32 is provided over approximately the entire supply path 31. The flow adjusters and the on-off valves are provided at each branching point of the supply path 31 to adjust a supply amount of the supercritical fluid and to switch the supply and cutoff of the supercritical fluid.

The fluid discharger 40 has a discharge path 41 connected to a discharge header 29 of the processing container 10 and discharges the fluid in the processing chamber 11 via the discharge path 41. The discharge header 29 is provided on the front side (on the loading/unloading port 15p side) of the bottom wall 13 of the processing container 10. A discharge port 29a of the discharge header 29 is open on an upper surface of the bottom wall 13 to communicate with the processing chamber 11. The fluid discharged to the outside of the processing container 10 via the discharge header 29 contains vapor of drying liquid dissolved in the supercritical fluid, in addition to the supercritical fluid.

The fluid discharger 40 includes a discharge-side heater 42, as well as a flow adjuster, a pressure reduction valve, an on/off valve, a temperature sensor, a pressure sensor, a flow sensor, and the like, which are not illustrated, at intermediate positions of the discharge path 41. Further, a downstream end of the discharge path 41 is connected to a discharge mechanism (not illustrated) for processing the discharged supercritical fluid. The discharge-side heater 42 prevents the liquefaction of the fluid in the discharge path 41. For example, the discharge-side heater 42 is provided over the entire discharge path 41.

Meanwhile, the substrate transferor 50 is installed on the front side of the processing container 10 to receive or deliver the substrate W from or to a transfer device (not illustrated). Further, the substrate transferor 50 accommodates the substrate W in the processing container 10 or takes out the substrate W from the interior of the processing container 10 by moving the substrate W relative to the processing container 10. In particular, the substrate processing apparatus 1 according to the present embodiment performs the substrate processing, that is, the supercritical drying in the state where the substrate W is held by the substrate transferor 50.

Specifically, the substrate transferor 50 includes a substrate holder 51 for holding the substrate W, a forward/backward mover 54 for advancing or retracting the substrate holder 51 to or from the processing container 10, and a lift pin mechanism 55 for raising or lowering the substrate W to receive or deliver the substrate W from or to the transfer device. Further, the substrate holder 51 includes a tray 52 on which the substrate W is placed, and a cover 53 provided on a front edge of the tray 52.

The tray 52 is configured as a rectangular frame slightly larger than the diameter of the substrate W and is supported by the cover 53 to extend in the horizontal direction. When the tray 52 holds the substrate W horizontally, a surface of the substrate W with the liquid film faces upward in the vertical direction.

The cover 53 is formed as a rectangular block and moves integrally with the tray 52 to enter the recessed space 14, thereby blocking the loading/unloading port 15p of the processing container 10. A sealing member (not illustrated) for airtightly blocking the processing chamber 11 may be provided on the cover 53 and/or on the rear side of the processing container 10. Further, the loading/unloading mechanism 15 raises the front blocking member 19 when the cover 53 blocks the loading/unloading port 15p, thereby preventing the cover 53 from moving to the front opening 14f. Thus, the substrate processing apparatus 1 may prevent the substrate holder 51 from moving relative to the processing container 10 during the supercritical drying.

The forward/backward mover 54 is connected to the controller 90 of the substrate processing apparatus 1 and slides the substrate holder 51 along the horizontal direction under the control of the controller 90. For example, the forward/backward mover 54 reciprocates the substrate holder 51 between an outer position at which the reception or delivery of the substrate W is performed and an inner position where the tray 52 is positioned in the processing chamber 11 and the loading/unloading port 15p is blocked by the cover 53.

The lift pin mechanism 55 raises or lowers a plurality of (three or more) lift pins 56 when the tray 52 is at the outer position to receive or deliver the substrate W from or to the transfer device. In addition to the respective lift pins 56, the lift pin mechanism 55 includes, for example, a drive source connected to the controller 90 and a drive transmitter for transmitting the driving force of the drive source to the respective lift pins 56 (all not illustrated).

The heating mechanism 60 heats the ceiling wall 12 and the bottom wall 13 of the processing chamber 10 to heat the interior of the processing chamber 11 from above and below the processing chamber 11, thereby maintaining the interior of the processing chamber 11 at a predetermined temperature. A specific configuration of the heating mechanism 60 will be described later in detail.

Further, the substrate processing apparatus 1 includes a temperature meter 70 configured to measure the temperature of the substrate W accommodated in the processing chamber 11 and transmit temperature information on the measured temperature to the controller 90. For example, the temperature meter 70 includes an indoor temperature sensor 71 for measuring the temperature of the processing chamber 11, and a plurality of heater temperature sensors 72 for measuring the temperature of each of a plurality of sensor heater units 61 of the heating mechanism 60, which will be described later. In addition, the substrate processing apparatus 1 may include either the indoor temperature sensor 71 or each heater temperature sensor 72, as a component to acquire the temperature of the processing chamber 11.

The controller 90 of the substrate processing apparatus 1 may include a computer equipped with a processor 91, a memory 92, as well as an input/output interface, electronic circuit, and the like, which are not illustrated. The processor 91 is a combination of one or more circuits such as a central processing unit (CPU), a graphics processing unit (GPU), an application specific integrated circuit (ASIC), a field-programmable gate array (FPGA), and a plurality of discrete semiconductors. The memory 92 is a combination of a volatile memory and a non-volatile memory (for example, a compact disk, a digital versatile disc (DVD), a hard disk, a flash memory, or the like.) as appropriate. In addition, the controller 90 may further include an integrated control device to control the operation of a plurality of substrate processing apparatuses. In this case, the controller 90 may be constituted with a host computer or a plurality of nodes that communicate information via a network.

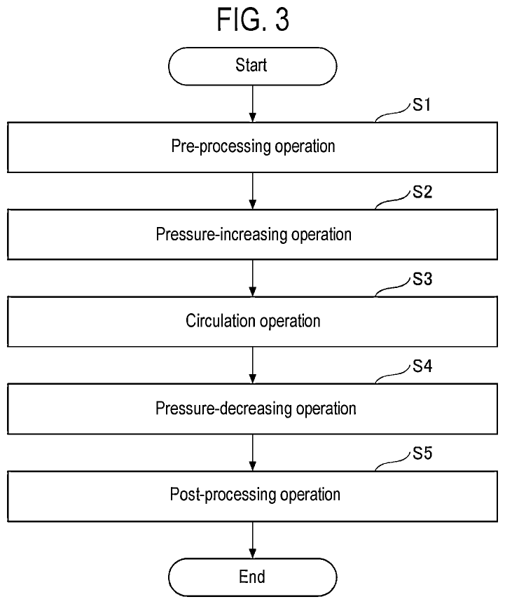

The memory 92 stores programs for controlling various processing executed in the substrate processing apparatus 1. The controller 90 causes the processor 91 to execute the programs stored in the memory 92, thereby controlling the operation of each component of the substrate processing apparatus 1. The controller 90 executes, for example, a processing flow of a substrate processing method illustrated in FIG. 3.

In the substrate processing method, in Step S1 as a pre-processing operation, the substrate W is accommodated in the processing chamber 11 of the processing container 10. At this time, the controller 90 of the substrate processing apparatus 1 raises each lift pin 56 to receive the substrate W with the liquid film of drying liquid from the transfer device, and lowers each lift pin 56 to place the substrate W on the tray 52 of the substrate holder 51. Further, the controller 90 operates the forward/backward mover 54 to slide the substrate holder 51 in the horizontal direction and accommodate the substrate W into the processing chamber 11 from the loading/unloading port 15p. When the cover 53 comes into contact with a rear wall defining the recessed space 14 to block the loading/unloading port 15p, the controller 90 operates the lifting drive 20 of the loading/unloading mechanism 15 to advance each front blocking member 19 to each through-hole 18 in the upper wall 16, thereby fixing the cover 53 to seal the processing chamber 11.

Subsequently, in Step S2 as a pressure-increasing operation, the controller 90 controls the fluid supplier 30 to supply the supercritical fluid to the processing chamber 11 of the processing container 10, while blocking the discharge path 41 of the fluid discharger 40. Thus, the internal pressure of the processing chamber 11 is increased to a set pressure, which is equal to or higher than the critical pressure of the supercritical fluid. Further, in the pressure-increasing operation, the controller 90 supplies the supercritical fluid to the processing chamber 11 only from the second supply header 28, which prevents the shaking of the drying liquid on the upper surface of the substrate W or the like to prevent the collapse of uneven patterns.

Subsequently, in Step S3 as a circulation operation, the controller 90 controls the fluid supplier 30 to supply the supercritical fluid to the processing chamber 11 while discharging the fluid from the processing chamber 11 through the fluid discharger 40, thereby circulating the supercritical fluid above the substrate W. At this time, the controller 90 discharges the supercritical fluid to the processing chamber 11 from both the first supply header 27 and the second supply header 28. The controller 90 controls each flow adjuster so that the flow rate of the supercritical fluid supplied by the fluid supplier 30 is equal to the flow rate of the fluid discharged by the fluid discharger 40, thereby maintaining the internal pressure of the processing container 10 at the set pressure. Thus, the liquid film of the drying liquid is dissolved in the supercritical fluid and is replaced with the supercritical fluid, so that the substrate W is dried. The drying liquid dissolved in the supercritical fluid is discharged, together with the supercritical fluid, to the outside of the processing container 10 via the discharge path 41.

In Step S4 as a pressure-decreasing operation, the controller 90 stops the supply of the supercritical fluid from the fluid supplier 30 while continuing the discharge of the fluid from the processing chamber 11 by the fluid discharger 40, thereby reducing the internal pressure of the processing container 10 to approximate atmospheric pressure (0.1 MPa).

Lastly, in Step S5 as a post-processing operation, the controller 90 controls the lifting drive 20 to lower the front blocking member 19, and also operates the forward/backward mover 54 to retract the substrate holder 51 from the processing container 10. Thus, the cover 53 opens the loading/unloading port 15p of the processing container 10, and the substrate W placed on the tray 52 is unloaded to the outside of the processing container 10. Once the substrate holder 51 has retracted to the outer position, the controller 90 raises each lift pin 56 to lift the substrate W from the tray 52 and delivers the same to the transfer device that has approached.

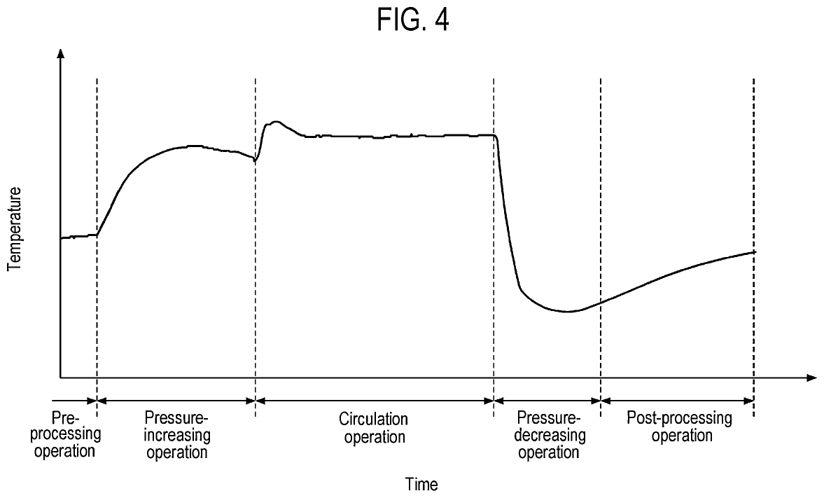

While executing the above-described substrate processing method, the controller 90 controls the output of the heating mechanism 60 based on a set temperature of the heating mechanism 60 to heat the processing chamber 11 and the substrate W. The higher the set temperature of the heating mechanism 60, the higher the output of the heating mechanism 60 is controlled. The output of the heating mechanism 60 is expressed as an amount of heat generated per unit time. While the set temperature of the heating mechanism 60 remains constant, the controller 90 maintains a constant output of the heating mechanism 60. While the set temperature of the heating mechanism 60 remains constant, the actual temperature of the processing chamber 11 (for example, the substrate W) varies over time, for example, as illustrated in the graph of FIG. 4. In addition, in the graph of FIG. 4, the horizontal axis represents time, and the vertical axis represents the temperature of the processing chamber 11. The set temperature of the heating mechanism 60 is basically the same throughout all operations but may be corrected at a desired timing. When the set temperature of the heating mechanism 60 is corrected, the output of the heating mechanism 60 is also corrected.

Specifically, in the pre-processing operation, the controller 90 heats the processing chamber 11 with the heating mechanism 60. Thus, the temperature of the processing chamber 11 is adjusted to be a state where the pressure-increasing operation of the supercritical drying may be initiated immediately.

In the subsequent pressure-increasing operation, the controller 90 supplies the supercritical fluid with the fluid supplier 30 while heating the processing chamber 11 with the heating mechanism 60. As the pressure of the processing chamber 11 increases due to the supply of the supercritical fluid, the temperature of the processing chamber 11 increases rapidly.

Then, when transitioning from the pressure-increasing operation to the circulation operation, the controller 90 supplies and discharges the supercritical fluid while heating the processing chamber 11 with the heating mechanism 60. Therefore, the temperature of the processing chamber 11 is maintained at an approximate constant optimal temperature for the supercritical drying (at or above the critical temperature).

In the subsequent pressure-decreasing operation, the controller 90 discharges the supercritical fluid with the fluid discharger 40 while heating the processing chamber 11 with the heating mechanism 60. In the pressure-decreasing operation, the temperature of the processing chamber 11 drops rapidly as the pressure of the processing chamber 11 is reduced. Thereafter, when the reduction of the pressure of the processing chamber 11 becomes gradual, the temperature of the processing chamber 11 gradually increases. In other words, the temperature of the processing chamber 11 in the pressure-decreasing operation follows a curve with a valley.

In the post-processing operation, the controller 90 heats the processing chamber 11 with the heating mechanism 60 to smoothly perform the next substrate processing. Thus, the temperature of the processing chamber 11 continues to gradually increase following the pressure-decreasing operation.

In addition, the graph illustrated in FIG. 4 is merely an example of temperature variations during the supercritical drying. In actual repetitions of the supercritical drying, the temperature of the processing chamber 11 varies due to various factors. For example, the temperature of the processing chamber 11 after the pre-processing operation may be different for each supercritical drying (for each substrate processing) due to effects such as temperature variations associated with the opening or closing of the loading/unloading port 15p and the heat storage of the processing container 10 during the supercritical drying. For example, the temperature of the processing chamber 11 gradually increases due to heat storage in the processing container 10. Thereafter, when the heat storage and heat dissipation of the processing container 10 are balanced, a constant temperature of the processing chamber 11 is achieved.

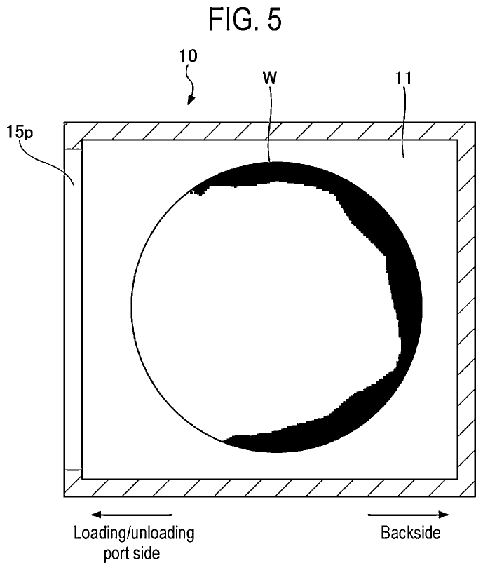

Further, the graph illustrated in FIG. 4 represents the average temperature of the entire processing chamber 11, and the temperature distribution of the substrate W accommodated in the processing chamber 11 may not become uniform. For example, as illustrated in FIG. 5, the temperature of the substrate W before the pre-processing operation tends to be higher at the back side of the processing container 10 and be lower toward the loading/unloading port 15p. This is because heat tends to be stored toward the back side of the processing chamber 11, while heat dissipates more easily toward the loading/unloading port 15p when the processing chamber 11 is open. As illustrated in FIG. 5, when the substrate W is subjected to the pressure-increasing operation and circulation operation with a significant difference in temperature distribution, uneven drying of the surface of the substrate W may occur, leading to the collapse of uneven patterns. In addition, in FIG. 5, a black portion of the substrate W represents a location with a higher temperature in the temperature distribution of the substrate W.

In other words, when adjusting the temperature of the processing chamber 11 during the supercritical drying, it is desirable to perform, for each implementation of the supercritical drying, both constant temperature control to make constant the temperature of the processing chamber 11 and temperature distribution uniformization control to prevent a difference in the in-plane temperature distribution of the substrate W.

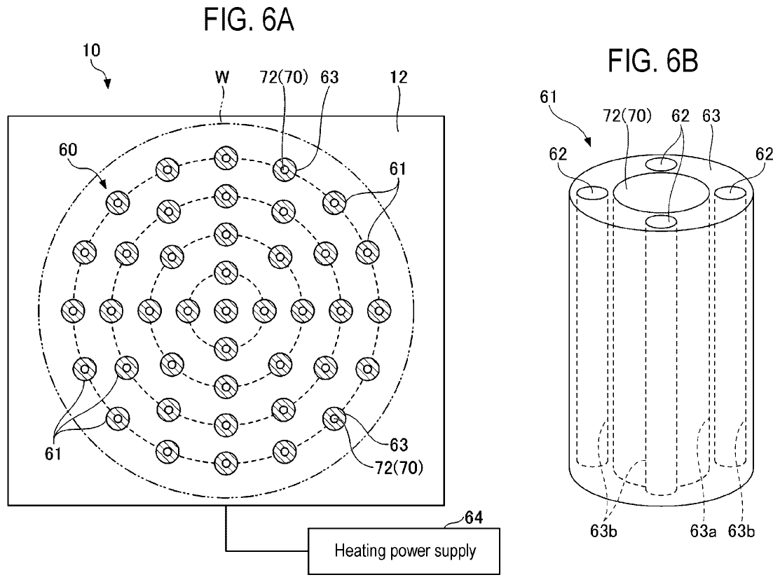

To perform the temperature distribution uniformization control, the heating mechanism 60 for heating the processing container 10 of the substrate processing apparatus 1 includes the plurality of sensor heater units 61 (container heaters), as illustrated in FIGS. 6A and 6B. The sensor heater units 61 are dispersedly arranged respectively at positions facing the substrate W moved to the inner position by the substrate transferor 50. Each sensor heater unit 61 is elongated along the vertical direction of the processing container 10 (see also FIG. 2). In detail, a plurality of virtual concentric circles with different radii are set with the center of the substrate W at the inner position as a reference point. The sensor heater units 61 are arranged at equal intervals on each virtual concentric circle so that the number of units is increased toward the outer virtual concentric circles from the center.

Further, each sensor heater unit 61 includes a plurality of (for example, four) rod-shaped heater bodies 62, a cylinder 63 for holding the respective heater bodies 62, and a heater temperature sensor 72 accommodated in the cylinder 63.

The plurality of heater bodies 62 are formed thinner than a thickness of the cylinder 63, and are respectively inserted into a plurality of peripheral holes 63b formed in the cylinder 63. Each heater body 62 is connected to a heating power supply 64 via wiring (not illustrated), and is individually raised in temperature by being supplied with power from the heating power supply 64. The cylinder 63 is made of a material with high thermal conductivity, and has a sensor placement hole 63a at the center as well as the plurality of peripheral holes 63b around the sensor placement hole 63a.

The heater temperature sensor 72 constituting the temperature meter 70 is integrated with each heater body 62 and the cylinder 63 by inserting a rod-shaped detector into the sensor placement hole 63a of the cylinder 63. The heater temperature sensor 72 may use, for example, a non-contact radiation temperature sensor configured to measure the temperature by collecting infrared rays emitted from the substrate W. The radiation-type heater temperature sensor 72 may highly accurately detect the temperature, which is applied to the substrate W by the respective heater bodies 62 at the same point, by measuring the temperature at the position facing the substrate W. Further, the heater temperature sensor 72 may be installed adjacent to the respective heater bodies 62, which are actually raised in temperature inside the cylinder 63, which makes it possible to measure the temperature without interference of an external temperature of the cylinder 63.

As illustrated in FIG. 2, each heater temperature sensor 72 provided on the ceiling wall 12 measures a temperature of the upper surface of the substrate W, while each heater temperature sensor 72 provided on the bottom wall 13 measures a temperature of the lower surface of the substrate W. Since the upper surface of the substrate W is covered with the liquid film of the drying liquid immediately after the substrate W is accommodated, the heater temperature sensor 72 on the ceiling wall 12 may measure the temperature of the liquid film. On the other hand, each heater temperature sensor 72 on the bottom wall 13 may directly detect the temperature of the substrate W by using the tray 52 having a hole at a location facing the heater temperature sensor 72. In addition, each heater temperature sensor 72 is not limited to being provided on both the ceiling wall 12 and the bottom wall 13, but may be provided on either one.

With the control of the heating power supply 64 by the controller 90, the heating mechanism 60 configured as described above may adjust a supply amount of power to each of the plurality of sensor heater units 61. Thus, the respective sensor heater units 61 may be adjusted in temperature independently of each other. Therefore, for example, as illustrated in FIG. 5, when the outer periphery of the substrate W has a high temperature, by reducing the temperature of the sensor heater unit 61 on the outer periphery below the temperature of the center of the substrate W, the uniformization of the in-plane temperature distribution of the substrate W is promoted.

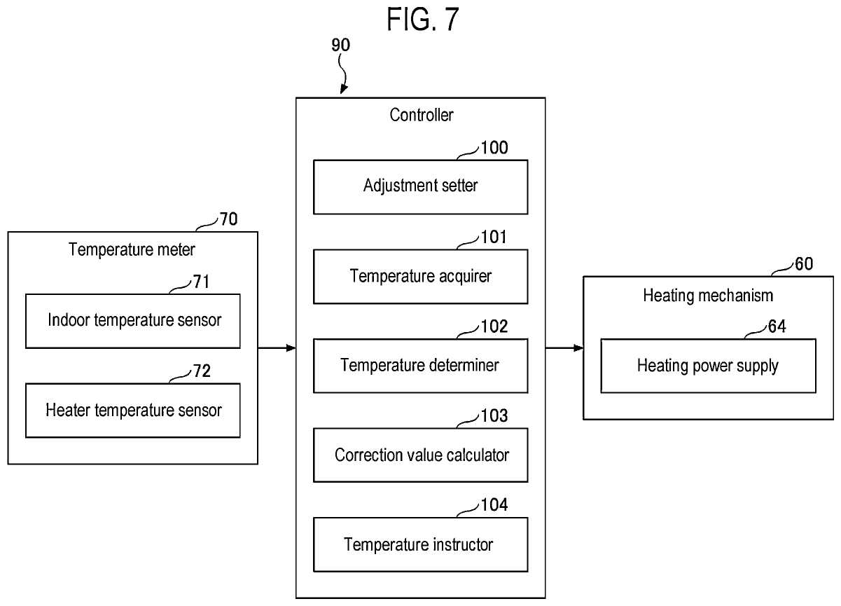

Further, in order to execute the constant temperature control, the controller 90 continuously samples a temperature of the supercritical drying in each operation and stores the same in the memory 92 to adjust a temperature adapted to perform the next supercritical drying based on the stored temperature information. Therefore, as illustrated in FIG. 7, the controller 90 incorporates therein an adjustment setter 100, a temperature acquirer 101, a temperature determiner 102, a correction value calculator 103, and a temperature instructor 104 to execute the supercritical drying.

The adjustment setter 100 allows a user to set a temperature adjustment target period for adjusting the temperature during the supercritical drying via a user interface (not illustrated) connected to the controller 90. The temperature adjustment target period may be set in units such as a pre-processing period during which the pre-processing operation is executed, a pressure-increasing period during which the pressure-increasing operation is executed, a circulation period during which the circulation operation is executed, a pressure-decreasing period during which the pressure-decreasing operation is executed, and a post-processing period during which the post-processing operation is executed. For example, the adjustment setter 100 displays the graph as illustrated in FIG. 4 and allows the user to select the temperature adjustment target period. In addition, the temperature adjustment target period may be automatically set by the controller 90 regardless of user's operation. Thus, the controller 90 may flexibly adjust the temperature according to the time of each operation in a recipe.

The temperature acquirer 101 acquires temperature information measured by the temperature meter 70 during the supercritical drying, and stores temperature-time data, in which the temperature information is associated with time information, in the memory 92. Therefore, the temperature-time data for each of multiple repetitions of the supercritical drying (for each substrate processing) is stored in the memory 92. In addition, the temperature-time data stored in the memory 92 may be automatically erased, for example, when shutting down the substrate processing apparatus 1, and new data may be accumulated when starting up the substrate processing apparatus 1.

Further, in a case where the plurality of heater temperature sensors 72 as described above are provided, the temperature-time data is stored for each of the plurality of heater temperature sensors 72. Thus, the controller 90 may monitor the temperature-time data for each of the plurality of heater temperature sensors 72 for each of multiple repetitions of the supercritical drying.

The temperature determiner 102 determines whether or not to correct the heating temperature of each sensor heater unit 61 based on the stored temperature-time data. For example, the temperature determiner 102 compares a reference temperature during the temperature adjustment target period with temperature information suitable for a temperature adjustment target period in temperature-time data measured during a current supercritical drying. Then, when the temperature information is equal to or higher than the reference temperature (or when the temperature information deviates from the reference temperature by a predetermined amount or more), the temperature determiner 102 determines that the correction is necessary. Conversely, when the temperature information is below the reference temperature (or when the temperature information deviates from the reference temperature by less than the predetermined amount), the temperature determiner 102 determines that the correction is not necessary.

As the reference temperature, temperature-time data acquired during a previous (last) supercritical drying may be used. Thus, the substrate processing apparatus 1 may continuously adjust the temperature to a constant value throughout multiple repetitions of the supercritical drying. Alternatively, the average value of temperature-time data obtained from multiple past measurements may be used as the reference temperature, or optimal temperature-time data obtained from experiments or simulations may be prepared in advance.

For example, in a case where the pressure-decreasing operation is set as the temperature adjustment target period for the constant temperature control, the temperature determiner 102 may compare the lowest temperature of the current pressure-decreasing operation with the lowest value of the reference temperature in the pressure-decreasing operation. Further, when the current lowest temperature has risen by a predetermined amount or more compared to the lowest value of the reference temperature, the correction is determined to be necessary. In addition, as the number of repetitions of the supercritical drying increases, the lowest temperature in the pressure-decreasing operation gradually increases due to heat storage in the processing container 10. Thereafter, the lowest temperature of the pressure-decreasing operation becomes constant as the heat storage and heat dissipation of the processing container 10 are balanced.

Further, in the case where the plurality of heater temperature sensors 72 is provided, the temperature determiner 102 determines the uniformity of the in-plane temperature distribution using the temperature information from the respective heater temperature sensors 72. For example, in a case where the pressure-increasing operation is set as the temperature adjustment target period for the temperature distribution uniformization control, the temperature determiner 102 extracts the measured temperature of each heater temperature sensor 72 at the same time point (for example, at the start of) in the pressure-increasing operation, and compares the measured temperature with a predetermined threshold range. Then, when the measured temperature falls outside the predetermined threshold range, the temperature determiner 102 determines that the correction of the temperature of the sensor heater unit 61 having the respective heater temperature sensor 72 is necessary. On the other hand, when the measured temperature falls within the predetermined threshold range, the temperature determiner 102 determines that the correction is not necessary.

Further, the correction value calculator 103 calculates a correction value for correcting the temperature of the sensor heater unit 61 when the temperature determiner 102 determines to perform the correction. A correction value in the constant temperature control is calculated as an appropriate value aiming to resolve a difference between the current temperature information during the temperature adjustment target period and the reference temperature during the same temperature adjustment target period.

For example, in a case where the pressure-decreasing operation is set as the temperature adjustment target period for the constant temperature control, when the lowest temperature of the current pressure-decreasing operation is higher than the lowest value of the reference temperature, a correction value (negative temperature) is calculated to lower the set temperature of the heating mechanism 60. This correction value (negative temperature) is reflected in the set temperature for the next supercritical drying. As a result, the temperature of the next supercritical drying will either match or sufficiently approach the reference temperature, which makes it possible to align the temperature of the post-processing operation and the temperature of the pre-processing operation or a temperature-increasing operation in the next supercritical drying. In other words, the lowest temperature of the pressure-decreasing operation serves as a starting point for the subsequent temperature increase, and the temperature at the starting point is aligned with the reference temperature so that the temperature of the processing chamber 11 may easily be controlled.

On the other hand, a correction value in the temperature distribution uniformization control is calculated as a value for resolving a difference between the measured temperatures of the respective heater temperature sensors 72 during the temperature adjustment target period for the temperature distribution uniformization control. For example, when the pressure-increasing operation is set as the temperature adjustment target period for the temperature distribution uniformization control, the measured temperatures of the respective heater temperature sensors 72 at the start of the current pressure-increasing operation are monitored. Then, for example, when the measured temperature of the heater temperature sensor 72 facing the outer periphery of the substrate W among the respective heater temperature sensors 72 is high, the correction value calculator 103 calculates a correction value to lower the temperature of the sensor heater unit 61 having the respective heater temperature sensor 72.

Further, it is desirable that the correction value in the temperature distribution uniformization control takes into account the correction value in the constant temperature control when the constant temperature control is performed. For example, when the correction value in the constant temperature control is −3 degrees C. and the difference in the temperature information of the heater temperature sensor 72 at the outer periphery of the substrate W is +2 degrees C., the correction value calculator 103 calculates a correction value of −5 degrees C. for that heater temperature sensor 72. Thus, the controller 90 may obtain a correction value that encompasses both the constant temperature control and the temperature distribution uniformization control.

The temperature instructor 104 calculates a temperature parameter of each sensor heater unit 61 based on the correction value calculated by the correction value calculator 103 and the set temperature for the supercritical drying. The temperature parameter may be a corrected set temperature based on the correction value when the correction is necessary, or may be the set temperature itself when the correction is not necessary. Then, during the next supercritical drying, the temperature instructor 104 sends instruction information regarding the calculated temperature parameter to the heating power supply 64. The heating power supply 64 adjusts the supply amount of power to each sensor heater unit 61 based on this instruction information, allowing each sensor heater unit 61 to heat the substrate W accommodated in the processing container 10 at an appropriate temperature.

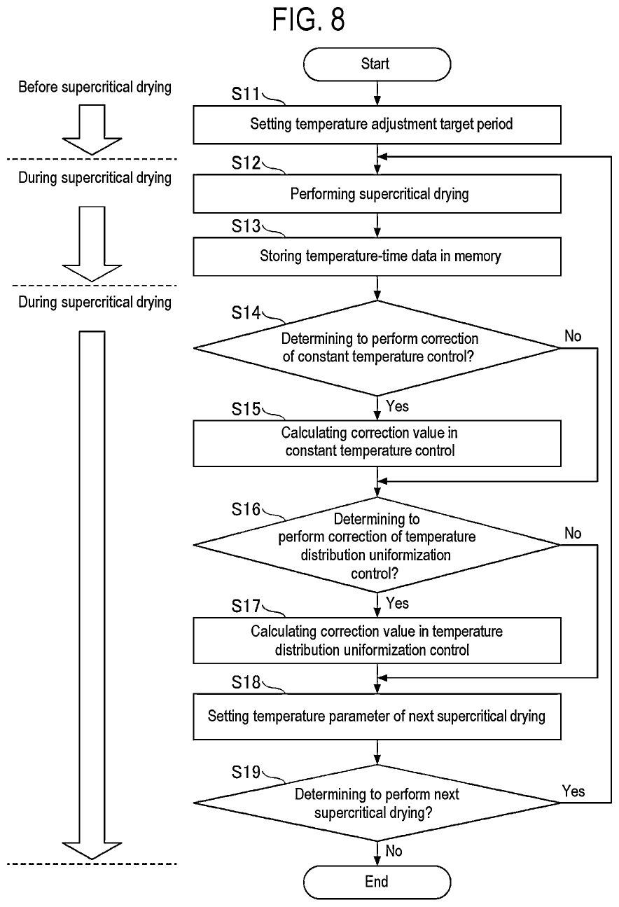

The substrate processing apparatus 1 according to the present embodiment is basically configured as described above. Hereinafter, an operation (substrate processing method) including both the constant temperature control and the temperature distribution uniformization control will be described with reference to FIG. 8.

First, the controller 90 of the substrate processing apparatus 1 controls the adjustment setter 100 to set a temperature adjustment target period for the supercritical drying before starting the supercritical drying (Step S11). In the following, a case where setting is made to perform the constant temperature control in the pressure-decreasing operation and the temperature distribution uniformization control in the pressure-increasing operation will be described.

Subsequently, the controller 90 of the substrate processing apparatus 1 executes the supercritical drying (Step S12). At this time, the controller 90 sequentially executes the pre-processing operation, the pressure-increasing operation, the circulation operation, the pressure-decreasing operation, and the post-processing operation according to the processing flow illustrated in FIG. 3. When a first round of supercritical drying is executed after the startup of the substrate processing apparatus 1, the controller 90 controls the temperature of the heating mechanism 60 at a set temperature without any correction.

Then, during the execution of the supercritical drying, the temperature acquirer 101 measures the temperature of the processing chamber 11 (the temperature of the substrate W) by the temperature meter 70 to acquire the temperature information of the temperature meter 70 and store the same as the temperature-time data in the memory 92 (Step S13).

After the current supercritical drying is completed, the controller 90 reads the current temperature-time data stored in the memory 92 and determines whether or not to perform the correction of the temperature in a subsequent round of supercritical drying based on the respective temperature-time data.

Specifically, the temperature determiner 102 determines whether or not to perform the correction of the constant temperature control by extracting the lowest temperature in the current pressure-decreasing operation and comparing the same with the lowest value of the stored reference temperature (Step S14). Then, when the current lowest temperature deviates from the lowest value of the reference temperature by a predetermined amount or more, the temperature determiner 102 determines to perform the correction of the constant temperature control and proceeds to Step S15. On the other hand, when the current lowest temperature deviates from the lowest value of the reference temperature by less than the predetermined amount, the temperature determiner 102 determines not to perform the correction of the constant temperature control and skips Step S15 to proceed to Step S16.

In Step S15, the correction value calculator 103 calculates a correction value in the constant temperature control. For example, when the current lowest temperature is higher than the lowest value of the reference temperature by a predetermined amount or more, the correction value calculator 103 calculates a correction value to lower the temperature of the heating mechanism 60. Conversely, when the current lowest temperature is lower than the lowest value of the reference temperature by a predetermined amount or more, the correction value calculator 103 calculates a correction value to raise the temperature of the heating mechanism 60.

Subsequently, the temperature determiner 102 determines whether or not to perform the correction of the temperature distribution uniformization control in the temperature-increasing operation using the current temperature-time data of each sensor heater unit 61 read from the memory 92 (Step S16). When the temperature of each sensor heater unit 61 is non-uniform, the temperature determiner 102 determines to perform the correction of the temperature distribution uniformization control and proceeds to Step S17. On the other hand, when the temperature of each sensor heater unit 61 is uniform, the temperature determiner 102 determines not to perform the correction of the temperature distribution uniformization control and skips Step S17 to proceed to Step S18.

In Step S17, the correction value calculator 103 calculates a correction value for each sensor heater unit 61 in the temperature distribution uniformization control. For example, when the temperature at the outer periphery of the substrate W is higher than the temperature at the center of the substrate W, the correction value calculator 103 calculates a correction value to lower the temperature of the sensor heater unit 61 facing the outer periphery of the substrate W. Further, when the correction value of the constant temperature control is calculated, the correction value calculator 103 takes into account the correction value of the constant temperature control when calculating the correction value for each sensor heater unit 61.

Then, the temperature instructor 104 sets a temperature parameter of the heating mechanism 60 in the next supercritical drying (Step S18). When it is determined that the correction is necessary in the current supercritical drying, the temperature instructor 104 resets the temperature parameter by adding the correction value calculated by the correction value calculator 103.

Thereafter, the controller 90 determines whether or not to perform the next supercritical drying (Step S19). When the next supercritical drying is determined to be performed, the controller 90 returns to Step S12 and repeats the same subsequent processing flow. Further, in the next supercritical drying, the temperature instructor 104 outputs instruction information of the set temperature parameter (corrected set temperature or uncorrected set temperature) to the heating power supply 64, thereby appropriately adjusting the temperature of the substrate W accommodated in the processing container 10.

The above-described substrate processing apparatus 1 performs feedforward control to heat the heating mechanism 60 with the temperature parameter set before performing the supercritical drying, without feed-backing the temperature measured by the temperature meter 70, during the supercritical drying. This makes it possible to stably perform temperature uniformization for each of multiple iterations of the supercritical drying while preventing minor variations in the temperature of the processing container 10.

As described above, the substrate processing apparatus 1 and the substrate processing method may promote the temperature uniformization for each substrate processing by determining whether or not the correction of the set temperature of the heating mechanism 60 is necessary based on the comparison between the temperature information during the temperature adjustment target period and the reference temperature. In other words, when the temperature information deviates from the reference temperature, the set temperature of the heating mechanism 60 may be corrected to bring the temperature of the next substrate processing closer to the reference temperature. This minimizes temperature variations for each substrate processing and stabilizes process performance throughout the substrate processing. As a result, it is possible to reliably maintain the state of uneven patterns of the substrate W.

Further, the substrate processing apparatus 1 may perform the temperature adjustment for each substrate processing on the basis of the lowest temperature in the pressure-decreasing operation by setting the pressure-decreasing operation of depressurizing the processing chamber 11 as the temperature adjustment target period. Thus, the temperature at the starting point of the temperature rise curve in which the temperature in the temperature adjustment is increased is aligned. This makes the temperature constant more easily.

Further, by providing the heating mechanism 60 with the plurality of sensor heater units 61, temperature adjustments of the respective sensor heater units 61 for the substrate W accommodated in the processing chamber 11 may be performed independently of each other. Further, the controller 90 may determine whether or not the temperature correction is necessary for each sensor heater unit 61, thus more easily making the in-plane temperature distribution of the substrate W uniform.

In the temperature distribution uniformization control, the controller 90 determines whether or not the correction of the temperature of each of the plurality of sensor heater units 61 is necessary based on the temperature information of the heater temperature sensor 72 provided in the corresponding sensor heater unit 61. Accordingly, the substrate processing apparatus 1 may adjust the temperature of each sensor heater unit 61 with higher precision.

In addition, the substrate processing apparatus 1 and the substrate processing method according to the present embodiment are not limited to the above embodiment and may take various modifications. For example, the substrate processing apparatus 1 may be configured to perform either the constant temperature control or the temperature distribution uniformization control, rather than performing both. For example, the substrate processing apparatus 1 may be configured to perform only the constant temperature control in which the temperature of the heating mechanism 60 for each supercritical drying (for each substrate processing) during the temperature adjustment target period is constant, without performing the temperature distribution uniformization control. Even in this case, the temperature uniformization for each supercritical drying may be achieved, which makes it possible to stabilize the process performance and maintain a state of uneven patterns of the substrate W substantially constant.

Further, the temperature adjustment target period for the constant temperature control during the supercritical drying is not limited to the pressure-decreasing operation, and may be set to any of the pre-processing operation, the pressure-increasing operation, the circulation operation, and the post-processing operation. For example, the substrate processing apparatus 1 may promote stabilization of the process performance by performing, as the constant temperature control in the pre-processing operation, correction to match a temperature before accommodating the substrate W in the processing chamber 11 to a temperature at the same timing. Further, by performing, as the constant temperature control in the post-processing operation, correction to match temperatures when the substrate W has been retrieved from the processing chamber 11, similar effects may be obtained. Alternatively, by performing, as the constant temperature control in the pressure-increasing operation, correction to match the temperature at the start of the pressure-increasing operation or when reaching a predetermined pressure to a temperature at the same timing, the process performance may be stabilized. Further, by performing, as the constant temperature control in the circulation operation, correction to match the temperature at the start or stop of the circulation operation, temperature non-uniformity across each supercritical drying may be suppressed.

Further, the temperature adjustment target period for the temperature distribution uniformization control during the supercritical drying is not limited to the pressure-increasing operation, and may be set to any of the pre-processing operation, the circulation operation, the pressure-decreasing operation, and the post-processing operation. For example, the substrate processing apparatus 1 may evenly heat the accommodated substrate W by performing, as the temperature distribution uniformization control in the pre-processing operation, correction to make the temperature of each sensor heater unit 61 uniform based on the temperature before accommodating the substrate W in the processing chamber 11. Further, by performing, as the temperature distribution uniformization control in the post-processing operation, correction to make the temperature of each sensor heater unit 61 uniform when the substrate W has been retrieved from the processing chamber 11, similar effects may be obtained. Alternatively, by performing, as the temperature distribution uniformization control in the circulation operation, correction to make the temperature at the start or end of the circulation operation uniform, temperature non-uniformity across each supercritical drying may vehicle suppressed. Further, by performing, as the temperature distribution uniformization control in the pressure-decreasing operation, correction to make the temperature of each sensor heater unit 61 uniform based on the lowest temperature in the pressure-decreasing operation may, the internal temperature of the processing chamber 11 may be appropriately adjusted.

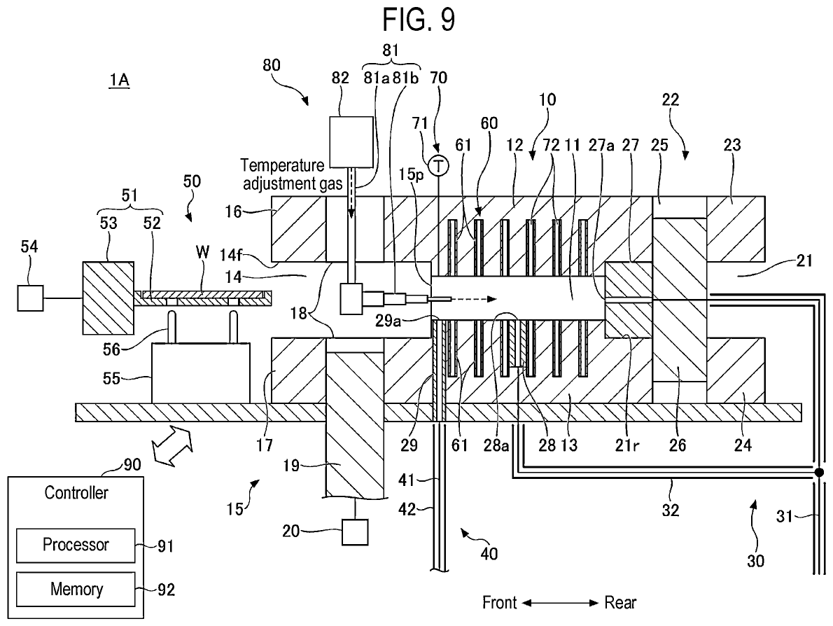

Further, a substrate processing apparatus 1A according to Modification illustrated in FIG. 9 differs from the above-described substrate processing apparatus 1 in that a temperature adjustment gas supplier 80 configured to spray a temperature adjustment gas into the processing chamber 11 of the processing container 10 is provided. The temperature adjustment gas sprayed from the temperature adjustment gas supplier 80 may be a cooling inert gas (for example, a N₂ gas) that is adjusted to a lower temperature than that of the processing container 10. For example, the temperature adjustment gas supplier 80 includes a driving nozzle 81 and an external supply mechanism 82 for supplying the temperature adjustment gas to the driving nozzle 81.

The driving nozzle 81 is formed in an L-shaped form and includes a base extension 81a that is movable toward and away from the recessed space 14, and a tip extension 81b that extends from a protruding end of the base extension 81a to enter or retract from the processing chamber 11 via the loading/unloading port 15p. The tip extension 81b of the driving nozzle 81 is configured to be mechanically extendable or retractable, and has a spout (not illustrated) for spraying the temperature adjustment gas therethrough at the tip thereof. In addition, in FIG. 9, the driving nozzle 81 is illustrated as being inserted into the loading/unloading port 15p via the through-hole 18 in the upper wall 16, but a path for inserting the driving nozzle into the loading/unloading port 15p is not particularly limited. For example, the driving nozzle may be configured to access the loading/unloading port 15p from the lateral side of the processing container 10.

The external supply mechanism 82 supplies the temperature adjustment gas to the driving nozzle 81 or stops the supply of the temperature adjustment gas under the control of the controller 90. For example, when it is determined that the correction of the temperature of the heating mechanism 60 is necessary after the completion of the supercritical drying (in the post-processing operation), the controller 90 executes the supply of the temperature adjustment gas by the temperature adjustment gas supplier 80.

The controller 90 controls the driving nozzle 81 to enter the processing chamber 11 of the processing container 10 at the timing when the substrate holder 51 retracts from the processing container 10. Then, after the driving nozzle 81 enters, the temperature adjustment gas is sprayed into the processing chamber 11 to adjust the temperature of the processing chamber 11. Also, at this time, the fluid discharger 40 discharges any gas as well as the temperature adjustment gas remaining in the processing chamber 11 to the outside. Thus, the substrate processing apparatus 1A may lower the temperature of the processing chamber 11 in a short time, thereby shortening the duration of the constant temperature control.

In addition, the substrate processing apparatus 1A may include a sensor (not illustrated) to detect a position of the spout of the driving nozzle 81 and may vary an extension length (position of the spout) of the tip extension 81b based on the detection result of the sensor. Thus, the driving nozzle 81 is positioned at an appropriate position (for example, inward) of the processing chamber 11 so that the temperature adjustment gas may be directly sprayed onto an area where cooling is more intensively performed. This makes it possible to further prompt uniformization of the in-plane temperature distribution of the substrate W.

The substrate processing apparatus 1 and the substrate processing method according to the embodiment disclosed herein are exemplary and not limitative in all respects. The embodiment may be modified and improved in various forms without departing from the scope of the appended claims and their gist. The items described in the above multiple embodiments may also take other configurations within a range that is not contradictory, and may be combined within a range that is not contradictory.

This application claims priority based on Japanese Patent Application No. 2022-18193 filed with the Japan Patent Office on Feb. 8, 2022, and the entire disclosure of which is incorporated herein in its entirety by reference.

### EXPLANATION OF REFERENCE NUMERALS

1: substrate processing apparatus, 10: processing container, 30: fluid supplier, 60: heating mechanism, 70: temperature meter, 90: controller, W: substrate

1-14. (canceled)

15. A substrate processing apparatus for drying a substrate having a liquid film using a supercritical fluid, comprising:
a processing container accommodating the substrate;
a fluid supplier configured to supply the supercritical fluid to an interior of the processing container;
a heating mechanism configured to heat the interior of the processing container;
a temperature meter configured to measure a temperature of the interior of the processing container; and
a controller configured to control the fluid supplier and the heating mechanism,
wherein the controller is configured to:
acquire temperature information on the temperature of the interior of the processing container measured by the temperature meter during a duration from when the substrate is loaded to the interior of the processing container until the substrate is unloaded from the processing container, and store temperature-time data in which the temperature information is associated with time;
extract a temperature during a temperature adjustment target period from the stored temperature-time data, and determine whether or not correction of a set temperature of the heating mechanism is necessary based on comparison between the temperature during the temperature adjustment target period and a reference temperature held in advance; and
when the correction of the set temperature is determined to be necessary, correct the set temperature and control an output of the heating mechanism according to the corrected set temperature.

16. The substrate processing apparatus of claim 15, wherein the duration has:
a pressure-increasing period during which a pressure of the interior of the processing container is increased to a set pressure after the substrate is loaded to the interior of the processing container;
a circulation period during which the supercritical fluid circulates at the set pressure to process the substrate; and
a pressure-decreasing period during which the pressure of the interior of the processing container is decreased after the substrate is processed, and
wherein the temperature adjustment target period is the pressure-decreasing period.

17. The substrate processing apparatus of claim 16, wherein the controller is configured to:
extract a lowest temperature of the temperature-time data in the pressure-decreasing period;
when the lowest temperature is equal to or higher than the reference temperature, determine that the correction of the set temperature is necessary; and
when the lowest temperature is less than the reference temperature, determine that the correction of the set temperature is not necessary.

18. The substrate processing apparatus of claim 17, wherein the reference temperature is a lowest temperature of temperature-time data in the pressure-decreasing period, which is acquired before the-temperature-time data.

19. The substrate processing apparatus of claim 18, wherein the heating mechanism includes a plurality of container heaters, temperatures of the plurality of container heaters being adjusted independently of each other, and
wherein the controller is configured to determine whether or not the correction of the set temperature is necessary for each of the plurality of container heaters.

20. The substrate processing apparatus of claim 19, wherein the plurality of container heaters are arranged to face an upper surface or a lower surface of the substrate accommodated in the interior of the processing container,
wherein the temperature meter includes a plurality of heater temperature sensors provided respectively in the plurality of container heaters, and
wherein the controller is configured to correct the set temperature of a respective container heater among the plurality of container heaters based on pieces of temperature information from the plurality of heater temperature sensors.

21. The substrate processing apparatus of claim 20, wherein the controller is configured to:
compare a measured temperature from each of the plurality of heater temperature sensors during the temperature adjustment target period with a predetermined threshold range; and
when the measured temperature falls outside the predetermined threshold range, correct the set temperature of the respective container heater.

22. The substrate processing apparatus of claim 15, further comprising: a temperature adjustment gas supplier configured to supply a temperature adjustment gas to the interior of the processing container,
wherein, the correction of the set temperature is determined to be necessary, the controller controls the temperature adjustment gas supplier to supply the temperature adjustment gas.

23. The substrate processing apparatus of claim 15, wherein the controller controls the output of the heating mechanism to be constant when the set temperature remains constant during a supercritical drying that involves supplying the supercritical fluid to the substrate and drying the substrate.

24. The substrate processing apparatus of claim 15, wherein the heating mechanism includes a plurality of container heaters, temperatures of the plurality of container heaters being adjusted independently of each other, and
wherein the controller is configured to determine whether or not the correction of the set temperature is necessary for each of the plurality of container heaters.

25. The substrate processing apparatus of claim 24, wherein the plurality of container heaters are arranged to face an upper surface or a lower surface of the substrate accommodated in the interior of the processing container,
wherein the temperature meter includes a plurality of heater temperature sensors provided respectively in the plurality of container heaters, and
wherein the controller is configured to correct the set temperature of a respective container heater among the plurality of container heaters based on pieces of temperature information from the plurality of heater temperature sensors.

26. The substrate processing apparatus of claim 25, wherein the controller is configured to:
compare a measured temperature from each of the plurality of heater temperature sensors during the temperature adjustment target period with a predetermined threshold range; and
when the measured temperature falls outside the predetermined threshold range, correct the set temperature of the respective container heater.

27. A substrate processing method of drying a substrate having a liquid film using a supercritical fluid, the substrate processing method comprising:
performing a supercritical drying by loading the substrate to an interior of a processing container, supplying the supercritical fluid to the interior of the processing container, and heating the interior of the processing container with a heating mechanism;
acquiring temperature information on a temperature of the interior of the processing container measured by a temperature meter during a duration from when the substrate is loaded to the interior of the processing container until the substrate is unloaded from the processing container, and storing temperature-time data in which the temperature information is associated with time;
extracting a temperature during a temperature adjustment target period from the stored temperature-time data, and determining whether or not correction of a set temperature of the heating mechanism is necessary based on comparison between the temperature during the temperature adjustment target period and a reference temperature held in advance; and
when the correction of the set temperature is determined to be necessary, controlling an output of the heating mechanism according to a corrected set temperature.

28. The substrate processing method of claim 27, wherein the duration includes:
a pressure-increasing period during which the temperature of the interior of the processing container is increased to a set pressure after the substrate is loaded;
a circulation period during which the supercritical fluid circulates at the set pressure to process the substrate; and
a pressure-decreasing period during which a pressure of the interior of the processing container is decreased after the substrate is processed, and
wherein the determining whether or not correction of a set temperature is necessary includes:
extracting a lowest temperature from the temperature-time data during the pressure-decreasing period;
when the lowest temperature is equal to or higher than the reference temperature, determining that the correction of the set temperature is necessary; and
when the lowest temperature is below the reference temperature, determining that the correction of the set temperature is not necessary.

29. The substrate processing method of claim 28, wherein the heating mechanism includes a plurality of container heaters, temperatures of the plurality of container heaters being adjusted independently of each other, and
wherein the determining whether or not correction of a set temperature is necessary is performed for each of the plurality of container heaters.

30. The substrate processing method of claim 29, wherein the plurality of container heaters are arranged to face an upper surface or a lower surface of the substrate accommodated in the interior of the processing container, and
wherein the substrate processing method comprises: correcting the set temperature of a respective container heater among the plurality of container heaters based on temperature information from a plurality of heater temperature sensors provided respectively in the plurality of container heaters.

31. The substrate processing method of claim 30, wherein, during the heating by the heating mechanism, the determining whether or not correction of a temperature is necessary includes:
comparing a measured temperature from each of the plurality of heater temperature sensors during the temperature adjustment target period with a predetermined threshold range; and
when the measured temperature falls outside the predetermined threshold range, correcting the set temperature of the respective container heater.

32. The substrate processing method of claim 27, wherein the heating mechanism includes a plurality of container heaters, temperatures of the plurality of container heaters being adjusted independently of each other, and
wherein the determining whether or not correction of a set temperature is necessary is performed for each of the plurality of container heaters.

33. The substrate processing method of claim 32, wherein the plurality of container heaters are arranged to face an upper surface or a lower surface of the substrate accommodated in the interior of the processing container, and
wherein the substrate processing method comprises: correcting the set temperature of a respective container heater among the plurality of container heaters based on temperature information from a plurality of heater temperature sensors provided respectively in the plurality of container heaters.

34. The substrate processing method of claim 33, wherein, during the heating by the heating mechanism, the determining whether or not correction of a temperature is necessary includes:
comparing a measured temperature from each of the plurality of heater temperature sensors during the temperature adjustment target period with a predetermined threshold range; and
when the measured temperature falls outside the predetermined threshold range, correcting the set temperature of the respective container heater.
